(19) United States
(12) Patent Application Publication
(10) Pub. No.: US 2024/0116750 A1
(43) Pub. Date: Apr. 11, 2024

(54) MEMS MODULE

(71) Applicant: ROHM CO., LTD., Kyoto (JP)

(72) Inventor: Takashi NAIKI, Kyoto (JP)

(21) Appl. No.: 18/480,936

(22) Filed: Oct. 4, 2023

(30) Foreign Application Priority Data
Oct. 6, 2022 (JP) 2022-161574

(51) Int. Cl. B81B 7/00

(52) U.S. Cl. CPC B81B 7/0048; B81B 2201/0264; B81B 2207/07

(57) ABSTRACT

A MEMS module includes: a substrate; a semiconductor chip in which a MEMS including a mechanical movable portion is formed; and a soft member that is interposed between the substrate and the semiconductor chip and has a lower hardness than the substrate, wherein the soft member is disposed in a partial region of a first main surface of the semiconductor chip facing the substrate.

### CROSS-REFERENCE TO RELATED APPLICATION

This application is based upon and claims the benefit of priority from Japanese Patent Application No. 2022-161574, filed on Oct. 6, 2022, the entire contents of which are incorporated herein by reference.

### TECHNICAL FIELD

The present disclosure relates to a MEMS module.

### BACKGROUND

A micro electro mechanical system (MEMS), which is a device in which mechanical components and electronic circuits are integrated by using a micro-fabrication technology used in manufacturing a semiconductor integrated circuit, is known.

A MEMS includes, for example, a hollow portion and a movable portion configured to close the hollow portion. In a configuration disclosed in the related art, the hollow portion is formed by bonding a glass substrate to a rear side of a Si substrate in which a recess is formed. Such a bonding is required to prevent generation of a minute gap when the hollow portion is sealed.

The MEMS may also be used by being incorporated into a MEMS module that may be used as a pressure sensor. A change in an external air pressure changes a stress generated at an end of a movable portion of the MEMS, and a gauge resistance changes according to deformation of the movable portion. The pressure sensor outputs the change in the gauge resistance as a change in an output voltage.

### BRIEF DESCRIPTION OF DRAWINGS

The accompanying drawings, which are incorporated in and constitute a part of the specification, illustrate embodiments of the present disclosure.

FIG. 1A is a top view showing a MEMS module according to a first embodiment of the present disclosure

FIG. 1B is a cross-sectional view taken along line IB-IB in FIG. 1A.

FIG. 2 is a cross-sectional view showing a detailed structure of a substrate shown in FIGS. 1A and 1B.

FIG. 3 is a cross-sectional view showing a detailed structure of a MEMS shown in FIGS. 1A and 1B.

FIG. 4A is a top view showing a MEMS module according to a first modification of the first embodiment of the present disclosure.

FIG. 4B is a cross-sectional view taken along line IVB-IVB in FIG. 4A.

FIG. 5A is a top view showing a MEMS module according to a second modification of the first embodiment of the present disclosure.

FIG. 5B is a cross-sectional view taken along line VB-VB in FIG. 5A.

FIG. 6 is a top view showing a MEMS module according to a third modification of the first embodiment of the present disclosure.

FIG. 7 is a cross-sectional view showing a MEMS module according to a fourth modification of the first embodiment of the present disclosure.

FIG. 8A is a top view showing a MEMS module according to a second embodiment of the present disclosure.

FIG. 8B is a cross-sectional view taken along line VIIIB-VIIIB in FIG. 8A.

FIG. 9A is a top view showing a MEMS module according to a first modification of the second embodiment of the present disclosure.

FIG. 9B is a cross-sectional view taken along line IXB-IXB in FIG. 9A.

FIG. 10A is a top view showing a MEMS module according to a second modification of the second embodiment of the present disclosure.

FIG. 10B is a cross-sectional view taken along line XB-XB in FIG. 10A.

FIG. 11 is a top view showing a MEMS module according to a third modification of the second embodiment of the present disclosure.

FIG. 12 is a cross-sectional view showing a MEMS module according to a fourth modification of the second embodiment of the present disclosure.

FIG. 13 is a cross-sectional view showing a barometer.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Next, some embodiments will be described with reference to the drawings. In the description of the drawings described below, the same or similar parts are denoted by the same or similar reference numerals. However, it should be noted that the drawings are schematic, and a relationship between a thickness and a planar dimension of each component, and the like differ from actual ones. Therefore, specific thicknesses and dimensions should be determined with reference to the following description. In addition, it goes without saying that there are portions with different dimensional relationships and ratios among the drawings.

Further, in the present disclosure and the like, when a “stress” is simply written, it includes both a stress which is to be detected and a stress which is not to be detected.

Further, in the present disclosure and the like, “electrically connected” includes a case of being connected via “something having some electrical action.” Herein, “something having some electrical action” is not particularly limited as long as it enables transmission/reception of electrical signals to/from connection targets. For example, “something having some electrical action” includes electrodes, wirings, switching elements, resistive elements, inductors, capacitive elements, and other elements having various functions.

Further, in the present disclosure and the like, “mechanically connected” includes a case of being connected via “something that propagates a physical force such as pressure.” That is, “mechanically connected” includes a case where connection targets are directly connected and a case where connection targets are indirectly connected. Herein, “something that propagates a physical force” is not particularly limited as long as it enables transmission/reception of a physical force to/from connection targets.

In addition, embodiments of the present disclosure shown below are examples of devices and methods embodying technical ideas, and do not specify a material, a shape, a structure, an arrangement, and the like of each component. Various modifications may be made to the embodiments of the present disclosure within the scope of the claims.

Specific aspects of the embodiments of the present disclosure are as follows.

<1> A MEMS module including: a substrate; a semiconductor chip on which a MEMS including a mechanical movable portion is formed; and a soft member that is interposed between the substrate and the semiconductor chip and has a lower hardness than the substrate, wherein the soft member is disposed in a partial region of a first main surface of the semiconductor chip facing the substrate.

<2> The MEMS module of <1>, further including: a hard member configured to mechanically connect the substrate and the semiconductor chip and has a higher hardness than the soft member, wherein when the MEMS module is viewed from a normal direction of the first main surface, the hard member is disposed at one of a plurality of corner portions of a periphery of the first main surface.

<3> The MEMS module of <1> or <2>, wherein the semiconductor chip includes a plurality of electrode pads that are formed on at least one selected from the group of the first main surface and a second main surface opposite the first main surface and configured to obtain electrical connection with an outside, and wherein when the MEMS module is viewed from the normal direction of the first main surface, the plurality of electrode pads are arranged at one of a plurality of corner portions of the first main surface or the second main surface.

<4> The MEMS module of <2>, wherein the hard member is a bump electrode configured to electrically connect the substrate and the semiconductor chip, and wherein the soft member is disposed in a region other than the one corner portion of the corner portions where the bump electrode is disposed.

According to <1> to <4>, even in a case where an external stress or the like is applied to the MEMS module including the substrate, the soft member is deformed to relax a non-detection target stress applied to the MEMS module, such that an influence of the non-detection target stress on characteristics of the MEMS module may be suppressed. As a result, it is possible to accurately obtain the characteristics of the MEMS module according to a detection target stress.

<5> The MEMS module of <4>, wherein when the MEMS module is viewed from the normal direction of the first main surface, the soft member is disposed at another corner portion diagonal to the one corner portion where the bump electrode is disposed.

According to <5>, when an external stress or the like is applied to the MEMS module including the substrate, the hard member (bump electrode) and the soft member serve as supporting points, such that it is possible to distribute the non-detection target stress in all directions of the first main surface of the semiconductor chip in the MEMS module.

<6> The MEMS module of <3>, wherein the plurality of electrode pads are formed on the second main surface of the semiconductor chip, the MEMS module further includes a metal wire electrically connected to the plurality of electrode pads, and the semiconductor chip is mounted on the substrate via the soft member.

<7> The MEMS module of <6>, wherein when the MEMS module is viewed from the normal direction of the first main surface, the soft member overlaps with the plurality of electrode pads.

According to <6> or <7>, since the soft member overlaps with the electrode pads, a physical load (such as tension) applied to the electrode pads due to connection of the metal wire may be efficiently released to the overlapping soft member, such that the load on the semiconductor chip may be reduced.

<8> The MEMS module of any one of <1> to <7>, wherein when the MEMS module is viewed from the normal direction of the first main surface, the soft member is disposed in a peripheral region of the first main surface, which is a region located within a predetermined distance from a periphery of the semiconductor chip toward a center of the semiconductor chip.

<9> The MEMS module of <8>, wherein when the MEMS module is viewed from the normal direction of the first main surface, the soft member is disposed at a corner portion of the peripheral region.

According to <8> and <9>, by disposing the soft member at the corner portion, a central region of the semiconductor chip may be effectively utilized (for example, utilized as an element mounting region).

<10> The MEMS module of <8>, wherein when the MEMS module is viewed from the normal direction of the first main surface, the soft member is disposed at an intermediate portion which is a portion of the peripheral region other than a corner portion of the peripheral region.

According to <10>, even in a case where an external stress or the like is applied to the MEMS module including the substrate, the soft member is deformed to further relax the non-detection target stress applied to the MEMS module, such that the influence of the non-detection target stress on the characteristics of the MEMS module may be suppressed. As a result, it is possible to accurately obtain the characteristics of the MEMS module according to the detection target stress.

<11> The MEMS module of any one of <1> to <10>, wherein when the MEMS module is viewed from the normal direction of the first main surface, the soft member includes a portion disposed outside the periphery of the semiconductor chip.

According to <11>, a stress applied to the MEMS module including the substrate may be released to a region outside the periphery of the semiconductor chip, thereby suppressing the influence of the non-target detection stress on the characteristics of the MEMS module. As a result, it is possible to accurately obtain the characteristics of the MEMS module according to the detection target stress.

<12> The MEMS module of any one of <1> to <7>, wherein when the MEMS module is viewed from the normal direction of the first main surface, the soft member is disposed in a central region that is separated by a predetermined distance from the periphery of the semiconductor chip toward the center of the semiconductor chip.

According to <12>, when an external stress or the like is applied to the MEMS module including the substrate, it is possible to distribute the non-detection target stress in all directions of the first main surface of the semiconductor chip in the MEMS module.

### First Embodiment

A configuration of a MEMS module 10 according to a first embodiment of the present disclosure will be described.

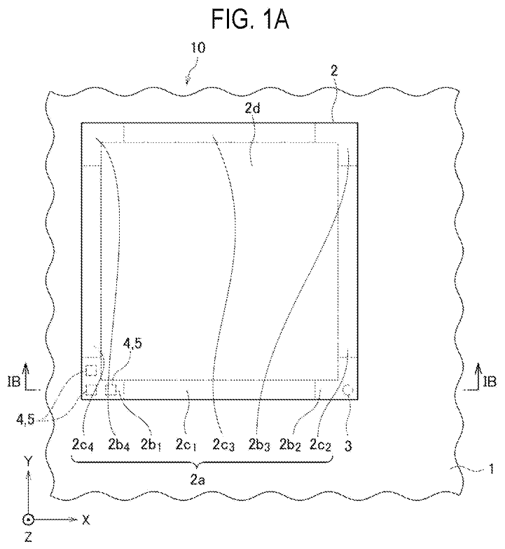

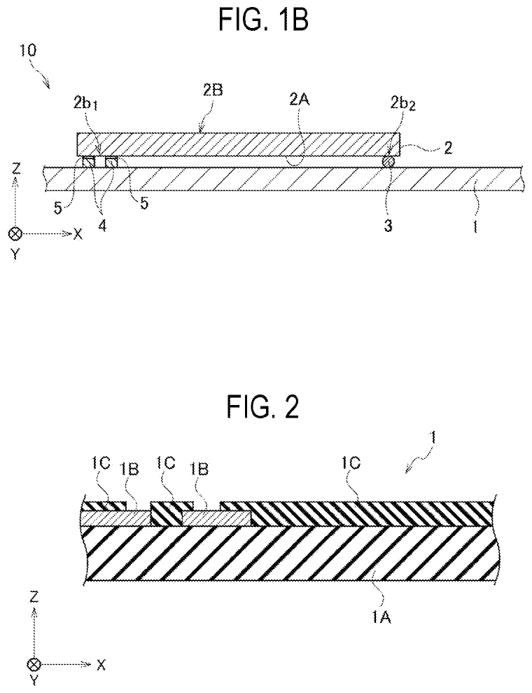

FIG. 1A is a top view showing the MEMS module 10. FIG. 1B is a cross-sectional view taken along line IB-IB of FIG. 1A. The MEMS module 10 includes a substrate 1, a semiconductor chip 2, a soft member 3 disposed between the substrate 1 and the semiconductor chip 2, and a hard member 4 configured to mechanically connect the substrate 1 and the semiconductor chip 2.

In the embodiment of the present disclosure, a thickness direction of the MEMS module 10 is referred to as a Z direction, a direction along one side of the MEMS module 10 orthogonal to the Z direction is referred to as an X direction, and a direction orthogonal to the Z direction and the X direction is referred to as a Y direction. In the embodiment of the present disclosure, the MEMS module 10 has, for example, an X-directional length of about 5 mm, a Y-directional length of about 5 mm, and a Z-directional length of about 0.8 mm to 1 mm.

As shown in FIG. 1B, the substrate 1 is a member configured to mount the semiconductor chip 2 via the soft member 3 and the hard member 4 and mount the MEMS module 10 on a circuit board of various electronic devices. As shown in FIG. 2, the substrate 1 includes a base 1A, a wiring portion 1B, and an insulating layer 1C. FIG. 2 is a cross-sectional view showing an enlarged portion of the substrate 1 connected to the hard member 4 in FIG. 1B. The specific configuration of the substrate 1 is not particularly limited as long as it may appropriately support the semiconductor chip 2 and the like, and an example thereof may include a printed circuit board.

The base 1A is made of an insulator and is a main constituent member of the substrate 1. Examples of materials for the base 1A may include glass epoxy resin, polyimide resin, phenol resin, ceramics, and the like. The base 1A has, for example, a rectangular plate shape in a plan view. In the present embodiment, the substrate 1 has an X-directional length of about 5 mm, a Y-directional length of about 5 mm, and a Z-directional length of about 100 to 200 μm.

The wiring portion 1B includes a region exposed to an opening portion of an insulating layer 1C, which will be described later, and the region and the hard member 4 are bonded together. Thus, the wiring portion 1B and the hard member 4 are electrically connected. The wiring portion 1B is made of, for example, one or more kinds of metals such as Cu, Ni, Ti, and Au, and is formed by, for example, plating.

The insulating layer 1C insulates and protects an appropriate portion of the wiring portion 1B by covering the appropriate portion. The insulating layer 1C is made of an insulating material, and is formed of, for example, a resist resin.

As shown in FIG. 1B, the semiconductor chip 2 has a first main surface 2A facing the substrate 1 and a second main surface 2B opposite the first main surface 2A. Further, to explain an arrangement position of the hard member 4 which will be described later, when the MEMS module 10 is viewed from a normal direction (Z direction) of the first main surface 2A, each of the first main surface 2A and the second main surface 2B is divided into a peripheral region 2a and a central region 2d. The peripheral region 2a is a region within a predetermined distance (for example, a distance that is twice the X-directional length of the hard member 4) from a periphery toward a center of the semiconductor chip 2. The central region 2d is a region other than the peripheral region 2a. Further, the peripheral region 2a is divided into corner portions 2b₁ to 2b₄ and intermediate portions 2c₁ to 2c₄ other than the corner portions 2b₁ to 2b₄. An X-directional length of the corner portion is, for example, three times the X-directional length of the hard member 4, and a Y-directional length of the corner portion is, for example, three times the Y-directional length of the hard member 4. In the present embodiment, a Z-direction length of the semiconductor chip 2 is, for example, about 200 to 300 μm, an X-direction length of the semiconductor chip 2 is, for example, about 1 to 3 mm, and a Y-direction length of the semiconductor chip 2 is, for example, about 1 to 3 mm. In the present embodiment, a shape of the semiconductor chip 2 is rectangular, but is not limited thereto, and may be formed in a shape of a polygon (including a regular polygon).

The semiconductor chip 2 includes a MEMS formed on a substrate including a semiconductor layer. Examples of the semiconductor layer may include a silicon layer and the like. The substrate of the semiconductor chip 2 may include, for example, only a semiconductor layer (silicon layer), or may include a laminated film of an oxide film, such as a silicon oxide layer, and a silicon layer. From the viewpoint of easy processing, the substrate of the semiconductor chip 2 is preferably made of silicon.

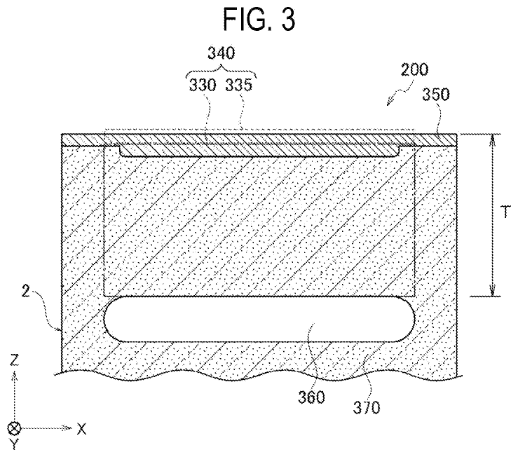

Herein, an example of a MEMS constituted as an atmospheric pressure sensor configured to detect an atmospheric pressure will be described. As shown in FIG. 3, a MEMS 200 mainly includes a movable portion 340, a hollow portion 360, and a fixed portion 370.

The movable portion 340 overlaps with the hollow portion 360 in the Z direction and is mechanically movable in the Z direction to detect the atmospheric pressure. A film thickness T of the movable portion 340 may be any thickness that allows a shape of the movable portion 340 to be deformed due to an atmospheric pressure difference between an internal atmospheric pressure of the hollow portion 360 and an atmospheric pressure outside the substrate including a semiconductor layer sandwiching the movable portion 340 (outside the semiconductor chip 2), and is, for example, 5 to 15 μm.

The hollow portion 360 is a cavity provided within the substrate including the semiconductor layer, and is sealed in the present embodiment. The hollow portion 360 may be a vacuum. A depth (Z-direction length) of the hollow portion 360 is, for example, 5 to 15 μm.

The fixed portion 370 is a portion configured to support the movable portion 340, and is a portion that is fixed to members such as the substrate 1 and the hard member 4 when the movable portion 340 operates. In the present embodiment, a portion of the substrate including the semiconductor layer other than the movable portion 340 and the hollow portion 360 is the fixed portion 370.

In the present embodiment, the movable portion 340 and the fixed portion 370 do not include bonding portions at a boundary therebetween, and are made of a single semiconductor such as silicon. The movable portion 340 includes a recess in a region 330. The recess is located in a region of the movable portion 340 that overlaps with the hollow portion 360 when viewed from the Z direction, and is gently recessed in the Z direction.

The recess is formed in a process of forming the hollow portion 360 inside the semiconductor chip 2. That is, after a process of interconnecting a plurality of grooves formed from an upper surface of the semiconductor chip 2 to form the hollow portion inside the semiconductor chip 2, the recess is formed in the surface of the semiconductor chip in a process of embedding the grooves from the surface to the hollow portion by a portion of the substrate including the semiconductor layer which is melted by heat treatment.

Since the film thickness T of the movable portion 340 is thin when the recess only closes the grooves, an interlayer film 350 may be formed on the substrate (the semiconductor chip 2) to increase the film thickness T. In the present embodiment, when the interlayer film 350 is provided, the interlayer film 350 functions as a part of the movable portion 340 and includes a region 335 overlapping with the region 330 of the semiconductor chip 2. Therefore, the movable portion 340 includes the region 330 of the semiconductor chip 2 and the region 335 of the interlayer film 350. The interlayer film 350 may be made of, for example, the same material as the semiconductor chip 2, and may be made of silicon. When the interlayer film 350 is provided, a surface on which a protective film (not shown) or the like formed on the interlayer film 350 is formed is a flat surface, which is preferable because coverage of the protective film is improved. In the present disclosure and the like, the “flat surface” includes a surface having an average surface roughness of 0.5 μm or less. The average surface roughness may be determined in accordance with, for example, JIS B 0601:2013 or ISO 25178.

Herein, the pressure sensor is exemplified as the MEMS, but without being limited thereto, the MEMS may be any MEMS that has a narrow gap existing between movable portions of the MEMS, between a movable portion and a fixed portion thereof, or between fixed portions thereof, exhibits a function by maintaining or changing an appropriate state of each of the movable portion and the fixed portion, and realizes, for example, a sensing function that uses a capacitance value, a sensing function that measures a resonance frequency, or a function that performs signal output and filtering to cause stable vibration.

The MEMS 200 includes a gauge resistor whose resistance value changes according to a shape (degree of distortion) of the movable portion 340. The gauge resistor is disposed at a boundary between the movable portion 340 and the fixed portion 370 where the greatest distortion occurs. Atmospheric pressure information may be acquired by measuring the resistance value of the gauge resistor.

As shown in FIG. 1A, the hard member 4 is disposed at one corner portion (herein, the corner portion 2b₁) of a plurality of corner portions (herein, the corner portions 2b₁ to 2b₄) of the peripheral region 2a of the first main surface 2A. Further, the hard member 4 has a higher hardness than the soft member 3. The hard member 4 may be, for example, a bump electrode electrically connecting the substrate 1 and the semiconductor chip 2. The bump electrode electrically connects an electrode pad 5, which is disposed at the corner portion 2b₁ of the peripheral region 2a of the first main surface 2A of the semiconductor chip 2, and the wiring portion 1B of the substrate 1. The hard member 4 is made of, for example, one or more kinds of metals such as Cu, Ni, Ti, and Au, and is formed by plating. In the present embodiment, three hard members 4 are arranged at the corner portion 2b₁, but the present disclosure is not limited thereto, and they may be arranged at, for example, the corner portion 2b₃ or the like in addition to the corner portion 2b₁. The electrode pad 5 is made of metal such as aluminum or an aluminum alloy, and is formed by, for example, sputtering or plating.

The soft member 3 has a lower hardness than the substrate 1. The soft member 3 is separated from the hard member 4 and is disposed in a partial region of the first main surface 2A of the semiconductor chip 2 facing the substrate 1. Specifically, the soft member 3 is disposed in a region (herein, the corner portion 2b₂) other than the corner portion 2b₁ where the hard member 4 is disposed. By disposing the soft members 3 at the corner portion, the central region 2d of the semiconductor chip 2 may be effectively used (for example, used as an element mounting region). The soft member 3 is not particularly limited as long as it is a material that is elastically deformed according to deformation of the substrate 1. For example, polyimide, silicone, or the like may be used for the soft member 3. Further, a shape of the soft member 3 is not limited to a spherical shape, and may be a rectangular shape, a linear shape, or the like.

In a mounting process or the like, when a non-detection target stress is applied to the MEMS module, a position or an angle of the movable portion of the MEMS at the time of design for detecting the detection target stress, or a size of a surrounding space changes, which inhibits accurate detection of characteristics of the MEMS module according to the detection target stress. Specifically, a narrow gap exists between movable portions of the MEMS, between a movable portion and a fixed portion thereof, or between fixed portions thereof, and a function is exhibited by maintaining or changing an appropriate state of each of the movable portion and the fixed portion. Examples of the function may include a sensing function that uses a capacitance value and the like, a sensing function that measures a resonance frequency, or a function that performs signal output and filtering to cause stable vibration. However, the non-detection target stress influences the maintenance or change of the appropriate states of the movable portion, the fixed portion, and the gap, and this influence inhibits accurate detection of the characteristics of the MEMS module according to the detection target stress.

However, in the present embodiment, since the soft member 3 has a lower hardness than the substrate 1, elastic deformation occurs between the substrate 1 and the semiconductor chip 2 according to deformation of the substrate 1 due to an external stress or the like. When the external stress or the like is applied to the MEMS module 10 including the substrate 1, the soft member 3 is deformed to contract, for example, in the Z direction. That is, even when the substrate 1 is deformed to be recessed toward the semiconductor chip 2 due to the external stress or the like, the soft member 3 is compressed to absorb the external stress or the like and make it difficult to transmit the stress to the semiconductor chip 2. On the other hand, when the MEMS module 10 is released from the external stress or the like applied to the MEMS module 10, the soft member 3 is deformed to return to its original shape. For example, the compressed soft member 3 expands to its original shape. When the external stress or the like applied to the MEMS module 10 is released from the MEMS module 10, it is preferable that the soft member 3 undergoes an ideal elastic deformation to completely return to its original shape. The elastic deformation of the soft member 3 may suppress the non-detection target stress applied to the substrate 1, and may suppress an influence of the non-detection target stress on the movable portion, such as a change in the movable portion.

The present disclosure is not limited thereto, and even in a state where an elasticity limit of the soft member 3 is exceeded and the soft member 3 does not return to its complete original shape, the soft member 3 is deformed to return to its original shape such that the non-detection target stress applied to the substrate 1 may be suppressed although relaxation of the non-detection target stress applied to the substrate 1 is small as compared with an ideal elastic deformation. Further, even in a case where the soft member 3 does not return to its original state, the deformation of the soft member 3 may reduce the influence of the non-detection target stress on the movable portion of the MEMS.

Since the soft member 3 is disposed not on the entire surface of the first main surface 2A of the semiconductor chip 2 but on a partial region (herein, the corner portion 2b₂), a space is formed between the substrate 1 and the first main surface 2A of the semiconductor chip 2. Therefore, for example, heat generated in the semiconductor chip 2 may be efficiently dissipated. Further, an amount of material used to form the soft member 3 may be reduced, which can reduce manufacturing cost.

According to the present embodiment, even in a case where the external stress or the like is applied to the MEMS module 10 including the substrate 1, the soft member 3 is deformed to relax the non-detection target stress applied to the semiconductor chip 2 and make it difficult to transmit the non-detection target stress to the semiconductor chip 2, such that the influence of the non-detection target stress on the characteristics of the MEMS module 10 can be suppressed. As a result, it is possible to accurately obtain the characteristics of the MEMS module 10 according to the detection target stress.

In the above-described MEMS module 10, the soft member 3 is disposed at the corner portion 2b₂, which is a region other than the corner portion 2b₁ where the hard member 4 is disposed, but the present disclosure is not limited thereto, and various modifications such as those shown below are possible.

### First Modification

A configuration of a MEMS module 20 according to a first modification will be described. First to fourth modifications of the first embodiment refer to the above description for common points with the MEMS module 10 shown in FIGS. 1A and 1B, and different points will be described below.

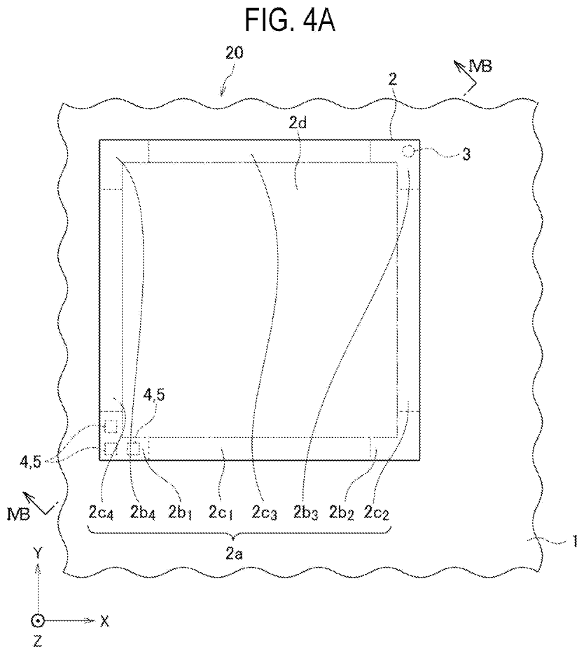

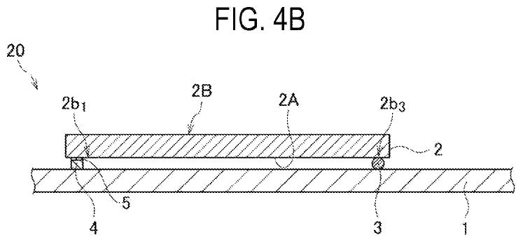

FIG. 4A is a top view showing the MEMS module 20 according to the first modification. FIG. 4B is a cross-sectional view taken along line IVB-IVB in FIG. 4A. The MEMS module 20 according to the first modification is different from the above-described MEMS module 10 shown in FIGS. 1A and 1B in that the soft member 3 is disposed at another corner portion diagonal to the corner portion of the first main surface 2A of the semiconductor chip 2 where the hard member 4 is disposed. Specifically, the hard member 4 is disposed at the corner portion 2b₁ of the first main surface 2A of the semiconductor chip 2, and the soft member 3 is disposed at the corner portion 2b₃ of the first main surface 2A of the semiconductor chip 2.

In the MEMS module 20, since the soft member 3 is disposed at the corner portion 2b₃ diagonal to the corner portion 2b₁ of the first main surface 2A of the semiconductor chip 2 where the hard member 4 is disposed, when an external stress or the like is applied to the MEMS module 20 including the substrate 1, the hard member 4 and the soft member 3 serve as supporting points, which makes it possible to distribute the stress in all directions of an X-Y plane of the MEMS module 20 including the substrate 1.

According to the first modification, even in a case where the external stress or the like is applied to the MEMS module 20 including the substrate 1, the soft member 3 is deformed to relax the non-detection target stress applied to the semiconductor chip 2 and, further, distribute the stress in all directions of the X-Y plane of the MEMS module 20, such that the influence of the non-detection target stress on the characteristics of the MEMS module 20 may be suppressed. As a result, it is possible to accurately obtain the characteristics of the MEMS module 20 according to the detection target stress.

### Second Modification

A configuration of a MEMS module 30 according to a second modification will be described.

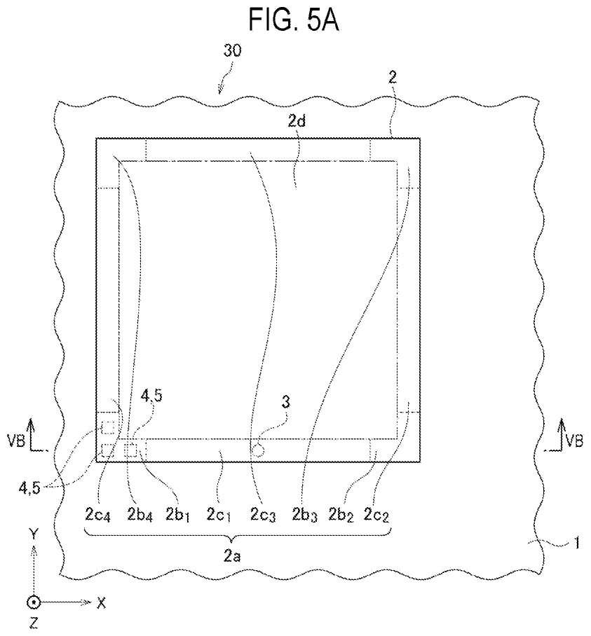

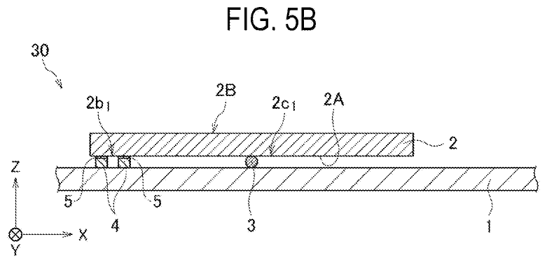

FIG. 5A is a top view showing the MEMS module 30 according to the second modification. FIG. 5B is a cross-sectional view taken along line VB-VB in FIG. 5A. The MEMS module 30 according to the second modification is different from the above-described MEMS module 10 shown in FIGS. 1A and 1B in that the soft member 3 is disposed at an intermediate portion 2ci of the first main surface 2A of the semiconductor chip 2.

In the MEMS module 30, since the soft member 3 is disposed at the intermediate portion 2ci between the corner portions 2b₁ and 2b₂ of the first main surface 2A of the semiconductor chip 2 on which the hard member 4 is disposed, a distance between the soft member 3 and the hard member 4 is shorter than that in the MEMS module 10. Therefore, when an external stress or the like is applied to the MEMS module 30 and the substrate 1 is deformed to be recessed toward the semiconductor chip 2, a degree of deformation of the soft member 3 is smaller than that in the MEMS module 10. That is, when the external stress or the like is the same, the deformation of the soft member 3 is smaller in the MEMS module 30 than in the MEMS module 10, such that the influence of the stress on the characteristics of the MEMS module 30 may be further suppressed.

According to the second modification, even in a case where the external stress or the like is applied to the MEMS module 30 including the substrate 1, the soft member 3 is deformed to further relax the non-detection target stress applied to the semiconductor chip 2, such that the influence of the non-detection target stress on the characteristics of the MEMS module 30 may be suppressed. As a result, it is possible to accurately obtain the characteristics of the MEMS module 30 according to the detection target stress.

### Third Modification

A configuration of a MEMS module 40 according to a third modification will be described.

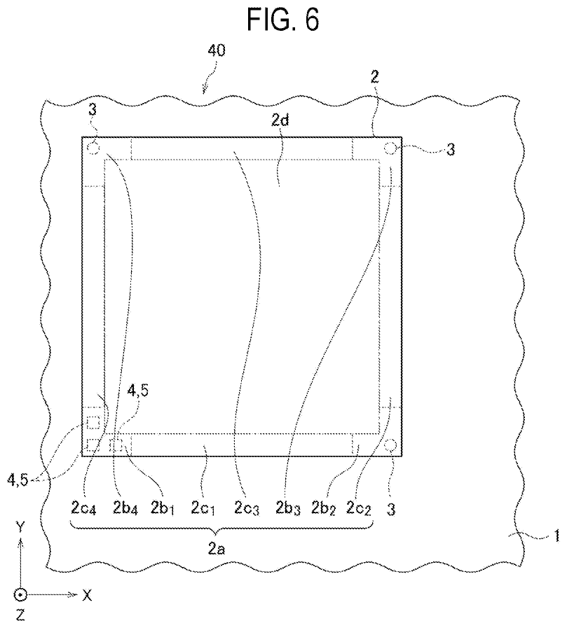

FIG. 6 is a top view showing the MEMS module 40 according to the third modification. The MEMS module 40 according to the third modification is different from the MEMS module 10 shown in FIGS. 1A and 1B in that a plurality of soft members 3 are arranged.

In the MEMS module 40, the soft members 3 are arranged at all the corner portions 2b₂ to 2b₄ other than the corner portion 2b₁ of the first main surface 2A of the semiconductor chip 2 where the hard member 4 is disposed. Since an external stress or the like is distributed by the plurality of soft members 3, an amount of deformation of one soft member 3 may be reduced.

According to the third modification, even in a case where the external stress or the like is applied to the MEMS module 40 including the substrate 1, the plurality of soft members 3 are deformed to further relax the non-detection target stress applied to the semiconductor chip 2 and make it difficult to transmit the non-detection target stress to the semiconductor chip 2, such that the influence of the non-detection target stress on the characteristics of the MEMS module 40 may be suppressed. As a result, it is possible to accurately obtain the characteristics of the MEMS module 40 according to the detection target stress.

### Fourth Modification

A configuration of a MEMS module 50 according to a fourth modification will be described.

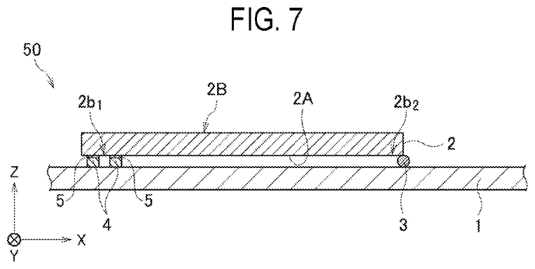

FIG. 7 is a cross-sectional view of the MEMS module 50 according to the fourth modification. The MEMS module 50 according to the fourth modification is different from the above-described MEMS module 10 shown in FIGS. 1A and 1B in that the soft member 3 includes a portion disposed outside the periphery of the semiconductor chip 2.

In the MEMS module 50, since the soft member 3 includes the portion disposed from the corner portion 2b₂ of the first main surface 2A of the semiconductor chip 2 to the outside of the periphery of the semiconductor chip 2, when an external stress or the like is applied to the MEMS module 50 including the substrate 1, the stress may be released to a region outside the periphery of the semiconductor chip 2 via the soft member 3.

According to the fourth modification, even in a case where the external stress or the like is applied to the MEMS module 50 including the substrate 1, the soft member 3 is deformed to relax the non-detection target stress applied to the semiconductor chip 2 and, further, release the stress applied to the MEMS module 50 to the region outside the periphery of the semiconductor chip 2, such that the influence of the non-detection target stress on the characteristics of the MEMS module 50 may be suppressed. As a result, it is possible to accurately obtain the characteristics of the MEMS module 50 according to the detection target stress.

Further, although not shown, one of the soft members 3 may be disposed in the central region 2d of the first main surface 2A of the semiconductor chip 2, and when an external stress or the like is applied to the MEMS module including the substrate 1, it is possible to distribute the stress in all directions of the X-Y plane of the MEMS module including the substrate 1.

In the present embodiment, the cases where the semiconductor chip 2 is mounted on the substrate 1 have been described, but the present disclosure is not limited thereto. The semiconductor chip 2 including the MEMS may be incorporated in a package such as ceramics or resin mold, or may be mounted in a multi-chip module. In these cases, the soft member 3 is disposed on structures including wirings, such as a wiring board, a lead frame, and a silicon chip, which assume at least some of wirings from pads of the MEMS to terminals of the package or the multi-chip module. By disposing the soft member 3 in these structures, even in a case where an external stress or the like is applied to the package or the multi-chip module, as described above, the soft member 3 may be deformed to relax the non-detection target stress applied to the semiconductor chip 2.

### Second Embodiment

A configuration of a MEMS module 60 according to a second embodiment will be described.

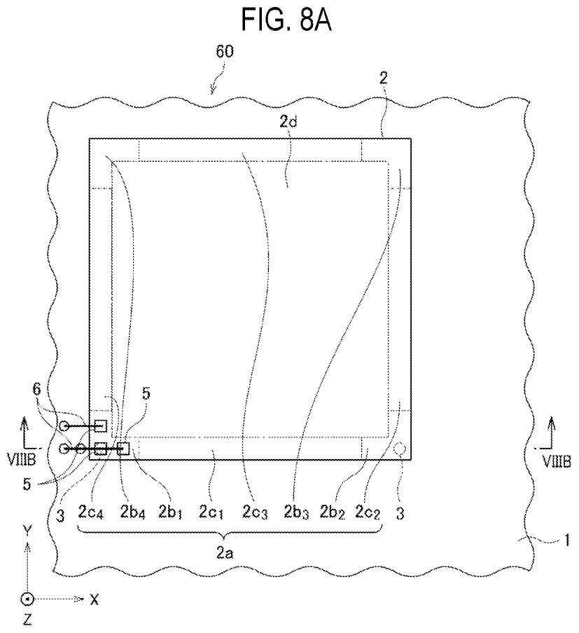

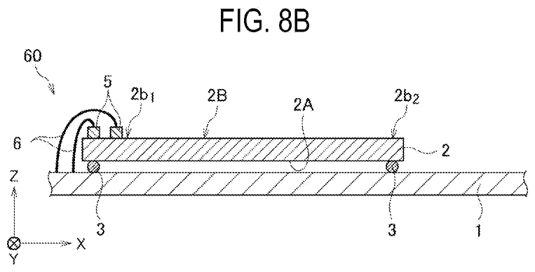

FIG. 8A is a top view showing the MEMS module 60. FIG. 8B is a cross-sectional view taken along line VIIIB-VIIIB in FIG. 8A. The MEMS module 60 includes a substrate 1, a semiconductor chip 2 including a plurality of electrode pads 5 configured to obtain electrical connection with the outside, a soft member 3 interposed between the substrate 1 and the semiconductor chip 2, and a metal wire 6 electrically connected to the electrode pads 5. The semiconductor chip 2 is mounted on the substrate 1 via the soft member 3. The MEMS module 60 according to the present embodiment is different from the above-described MEMS module 10 shown in FIGS. 1A and 1B in that the metal wire 6 replaces the hard member 4 (bump electrode) and the semiconductor chip 2 is mounted on the substrate 1 via the soft member 3 instead of the hard member. The second embodiment refers to the above description for common points with the MEMS module 10 shown in FIGS. 1A and 1B, and different points will be described below.

A plurality of electrode pads 5 are arranged at one corner portion (herein, the corner portion 2b₁) of the plurality of corner portions (herein, the corner portions 2b₁ to 2b₄) of the peripheral region 2a of the second main surface 2B of the semiconductor chip 2. The electrode pads 5 are made of metal such as aluminum or an aluminum alloy, and are formed by, for example, sputtering or plating. In the present embodiment, three electrode pads 5 are arranged at the corner portion 2b₁, but the present disclosure is not limited thereto. The three electrode pads 5 may be arranged at any one of the corner portions 2b₂, 2b₃, and 2b₄ instead of the corner portion 2b₁.

The metal wire 6 may be any wire configured to be capable of electrically connecting the electrode pads 5 and the wiring portion 1B of the substrate 1, and is made of, for example, metal such as Au. Material of the metal wire 6 is not limited, and may be Al, Cu, or the like.

The soft members 3 are arranged at the corner portions 2b₁ and 2b₂ of the first main surface 2A of the semiconductor chip 2. When the MEMS module 60 is viewed from a normal direction (Z direction) of the first main surface 2A, at least one of the soft members 3 overlaps with the electrode pads 5 arranged at the corner portion 2b₁ of the second main surface 2B of the semiconductor chip 2. Since the soft member 3 overlaps with the electrode pads 5, a physical load (such as tension) applied to the electrode pads 5 due to connection of the metal wire 6 may be efficiently released to the overlapping soft member 3, such that the load on the semiconductor chip 2 may be reduced.

Since the soft member 3 has a lower hardness than the substrate 1, as described above, it is elastically deformed between the substrate 1 and the semiconductor chip 2 according to the deformation of the substrate 1 due to an external stress or the like. When the external stress or the like is applied to the MEMS module 60 including the substrate 1, the soft member 3 is deformed to contract, for example, in the Z direction. That is, even when the substrate 1 is deformed to be recessed toward the semiconductor chip 2 due to the external stress or the like, the soft member 3 is compressed to absorb the external stress or the like and make it difficult to transmit the external stress to the semiconductor chip 2. On the other hand, when the MEMS module 60 is released from the external stress or the like applied to the MEMS module 60, the soft member 3 is deformed to return to its original shape. When the external stress or the like applied to the MEMS module 60 is released from the MEMS module 60, it is preferable that the soft member 3 undergoes an ideal elastic deformation to completely return to its original shape. The elastic deformation of the soft member 3 may suppress the non-detection target stress applied to the substrate 1, and may suppress the influence of the non-detection target stress on the movable portion, such as a change in the movable portion.

Further, as in the first embodiment, even in a state where the soft member 3 does not completely return to its original shape, the soft member 3 is deformed to return to its original shape, such that the non-detection target stress applied to the substrate 1 may be suppressed even though the relaxation of the non-detection target stress applied to the substrate 1 is small as compared with the ideal elastic deformation. Further, even in a case where the soft member 3 does not return to its original state, the deformation of the soft member 3 may reduce the influence of the non-detection target stress on the movable portion of the MEMS.

Since the soft member 3 is disposed not on the entire surface of the first main surface 2A of the semiconductor chip 2 but on a partial region (herein, the corner portion 2b₁) thereof, a space is formed between the substrate 1 and the first main surface 2A of the semiconductor chip 2. Therefore, for example, heat generated in the semiconductor chip 2 may be efficiently dissipated. Further, an amount of material used to form the soft member 3 may be reduced, which can reduce manufacturing cost.

According to the second embodiment, even in a case where the external stress or the like is applied to the MEMS module 60 including the substrate 1, the soft member 3 is deformed to relax the non-detection target stress applied to the semiconductor chip 2 and make it difficult to transmit the non-detection target stress to the semiconductor chip 2, such that the influence of the non-detection target stress on the characteristics of the MEMS module 60 may be suppressed. As a result, it is possible to accurately obtain the characteristics of the MEMS module 60 according to the detection target stress.

In the above-described MEMS module 60, the electrode pads 5 are arranged on the second main surface 2B of the semiconductor chip 2, but the present disclosure is not limited thereto. For example, the electrode pads 5 may be arranged only on the first main surface 2A of the semiconductor chip 2, or on the first main surface 2A and the second main surface 2B of the semiconductor chip 2. In other words, the electrode pads 5 are arranged on at least one selected from the group of the first main surface 2A and the second main surface 2B. Further, the metal wire 6 and the hard member 4 of the first embodiment may be used together. Further, the arrangement of the soft member 3 is not limited to the above-described arrangement, and may use various modifications such as those shown below.

### First Modification

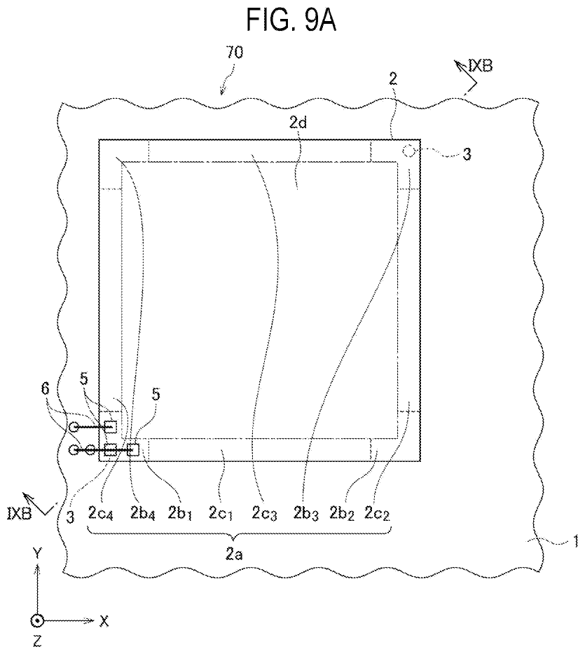

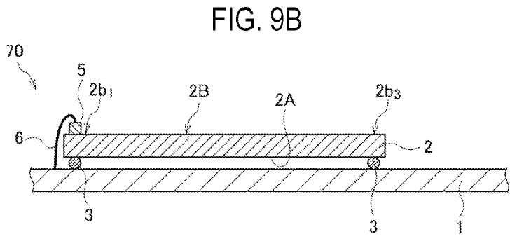

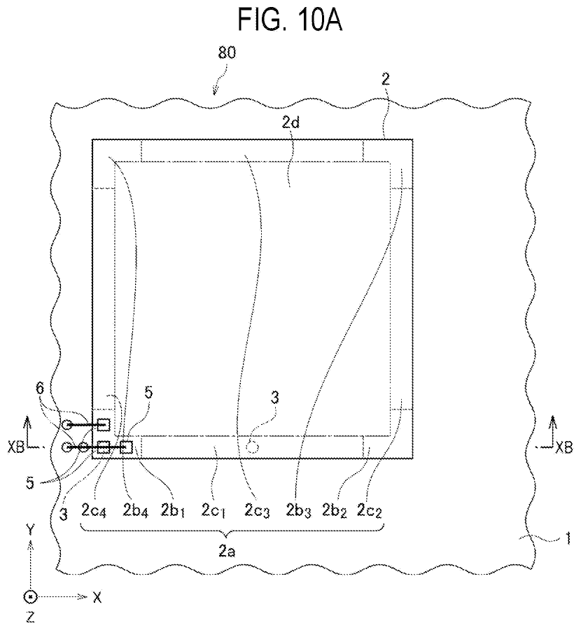

A configuration of a MEMS module 70 according to a first modification will be described. First to fourth modifications of the second embodiment refer to the above description for common points with the MEMS module 60 shown in FIGS. 8A and 8B, and different points will be described below. FIG. 9A is a top view showing the MEMS module 70 according to the first modification. FIG. 9B is a cross-sectional view taken along line IXB-IXB in FIG. 9A. The MEMS module 70 according to the first modification is different from the MEMS module 60 shown in FIGS. 8A and 8B in that soft members 3 are arranged at two diagonal corner portions of the first main surface 2A of the semiconductor chip 2. Specifically, one of the soft members 3 is disposed at the corner portion 2b₁ of the first main surface 2A of the semiconductor chip 2, and the other one of the soft members 3 is disposed at the corner portion 2b₃ of the first main surface 2A of the semiconductor chip 2.

In the MEMS module 70, since the soft members 3 are arranged at the two diagonal corner portions 2b₁ and 2b₃ of the first main surface 2A of the semiconductor chip 2, when an external stress or the like is applied to the MEMS module 70 including the substrate 1, the soft member 3 disposed at the corner portion 2b₁ and the soft member 3 disposed at the corner portion 2b₃ serve as supporting points, which makes it possible to distribute the stress in all directions of the X-Y plane of the MEMS module 70 including the substrate 1.

According to the first modification, even in a case where the external stress or the like is applied to the MEMS module 70 including the substrate 1, the soft member 3 is deformed to relax the non-detection target stress applied to the semiconductor chip 2 and, further, distribute the stress in all directions of the X-Y plane of the MEMS module 70, such that the influence of the non-detection target stress on the characteristics of the MEMS module 70 may be suppressed. As a result, it is possible to accurately obtain the characteristics of the MEMS module 70 according to the detection target stress.

### Second Modification

A configuration of a MEMS module 80 according to the second modification will be described.

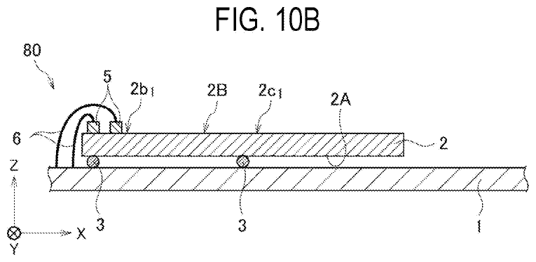

FIG. 10A is a top view showing the MEMS module 80 according to the second modification. FIG. 10B is a cross-sectional view taken along line XB-XB in FIG. 10A. The MEMS module 80 according to the second modification is different from the above-described MEMS module 60 shown in FIGS. 8A and 8B in that one of the soft members 3 is disposed at the intermediate portion 2ci of the first main surface 2A of the semiconductor chip 2.

In the MEMS module 80, since one of the soft members 3 is disposed at the corner portion 2b₁ of the first main surface 2A of the semiconductor chip 2 and the other one of the soft members 3 is disposed at the intermediate portion 2ci of the first main surface 2A of the semiconductor chip 2, a distance between the two soft members 3 is shorter than that in the MEMS module 60. Therefore, when an external stress or the like is applied to the MEMS module 80 and the substrate 1 is deformed to be recessed toward the semiconductor chip 2, a degree of deformation of the soft member 3 is smaller than that in the MEMS module 60. That is, when the external stress or the like is the same, the deformation of the soft member 3 is smaller in the MEMS module 80 than in the MEMS module 60, such that the influence of the stress on the characteristics of the MEMS module 80 may be further suppressed.

According to the second modification, even in a case where the external stress or the like is applied to the MEMS module 80 including the substrate 1, the soft member 3 is deformed to further relax the non-detection target stress applied to the semiconductor chip 2, such that the influence of the non-detection target stress on the characteristics of the MEMS module 80 may be suppressed. As a result, it is possible to accurately obtain the characteristics of the MEMS module 80 according to the detection target stress.

### Third Modification

A configuration of a MEMS module 90 according to a third modification will be described.

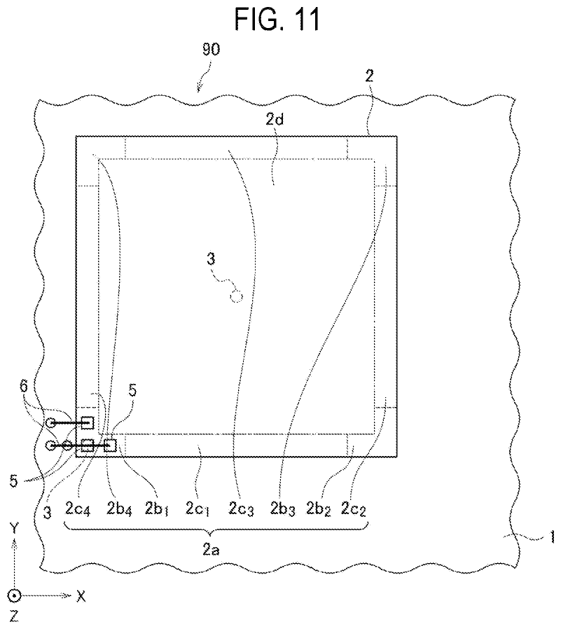

FIG. 11 is a top view showing the MEMS module 90 according to the third modification. The MEMS module 90 according to the third modification is different from the MEMS module 60 shown in FIGS. 8A and 8B in that one of the soft members 3 is disposed in the central region 2d of the first main surface 2A of the semiconductor chip 2.

In the MEMS module 90, since one of the soft members 3 is disposed in the central region 2d of the first main surface 2A of the semiconductor chip 2, when an external stress or the like is applied to the MEMS module 90 including the substrate 1, it is possible to distribute the stress in all directions of the X-Y plane of the MEMS module 90 including the substrate 1. Further, the MEMS module 90 has a distance between the two soft members 3 shorter than that of the MEMS module 60. Therefore, when the external stress or the like is applied to the MEMS module 90 and the substrate 1 is deformed to be recessed toward the semiconductor chip 2, a degree of contraction of the soft member 3 in the Z direction is smaller than that of the MEMS module 60. That is, when the external stress or the like is the same, the deformation of the soft member 3 is smaller in the MEMS module 90 than in the MEMS module 60, such that the influence of the stress on the characteristics of the MEMS module 90 may be further suppressed.

According to the third modification, even in a case where the external stress or the like is applied to the MEMS module 90 including the substrate 1, the soft member 3 is deformed to further relax the non-detection target stress applied to the semiconductor chip 2 and, further, distribute the stress in all directions of the X-Y plane of the MEMS module 90, such that the influence of the non-detection target stress on the characteristics of the MEMS module 90 may be suppressed. As a result, it is possible to accurately obtain the characteristics of the MEMS module 90 according to the detection target stress.

### Fourth Modification

A configuration of a MEMS module 100 according to a fourth modification will be described.

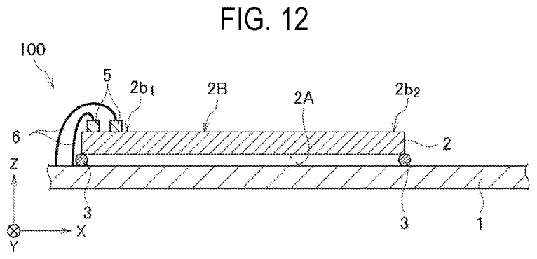

FIG. 12 is a cross-sectional view of the MEMS module 100 according to the fourth modification. The MEMS module 100 according to the fourth modification is different from the MEMS module 60 shown in FIGS. 8A and 8B in that the soft member 3 includes a portion disposed outside the periphery of the semiconductor chip 2.

In the MEMS module 100, since the soft members 3 include portions disposed from the corner portions 2b₁ to 2b₂ of the first main surface 2A of the semiconductor chip 2 to the outside of the periphery of the semiconductor chip 2, when an external stress or the like is applied to the MEMS module 100 including the substrate 1, the stress may be released to a region outside the periphery of the semiconductor chip 2 via the soft member 3.

According to the fourth modification, even in a case where the external stress or the like is applied to the MEMS module 100 including the substrate 1, the soft member 3 is deformed to relax the non-detection target stress applied to the semiconductor chip 2 and, further, release the stress applied to the MEMS module 100 to the region outside the periphery of the semiconductor chip 2, such that the influence of the non-detection target stress on the characteristics of the MEMS module 100 may be suppressed. As a result, it is possible to accurately obtain the characteristics of the MEMS module 100 according to the detection target stress.

In the present embodiment, the cases where the semiconductor chip 2 is mounted on the substrate 1 have been described, but the present disclosure is not limited thereto. The semiconductor chip 2 including the MEMS may be incorporated in a package such as ceramics or resin mold, or may be mounted in a multi-chip module. In these cases, the soft member 3 is disposed on structures including wirings, such as a wiring board, a lead frame, and a silicon chip, which assume at least some of the wirings from pads of the MEMS to terminals of the package or the multi-chip module. By disposing the soft member 3 on these structures, even in a case where the external stress or the like is applied to the package or the multi-chip module, as described above, the soft member 3 may be deformed to relax the non-detection target stress applied to the semiconductor chip 2.

### <Barometer>

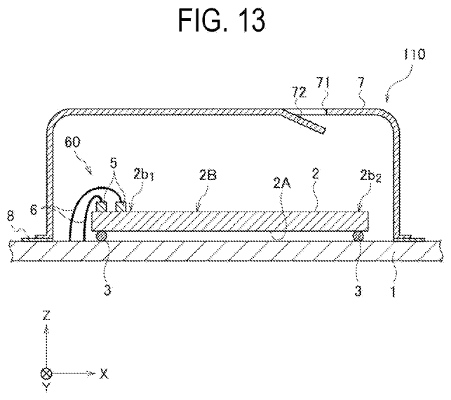

The MEMS modules shown in the first and second embodiments may be used, for example, as barometers. FIG. 13 shows a barometer 110 including the above-described MEMS module 60.

The barometer 110 includes the MEMS module 60 configured to suppress the influence of a stress from the outside, a cover 7, and a bonding material 8.

The cover 7 is a box-shaped member made of metal, and is bonded to the substrate 1 by the bonding material 8 so as to surround the MEMS module 60. The cover 7 may be made of a material other than metal. A method of manufacturing the cover 7 is not particularly limited. A space between the cover 7 and the substrate 1 is hollow or filled with soft resin such as silicone resin.

The cover 7 includes an opening portion 71 and an extending portion 72, as shown in FIG. 13. The opening portion 71 is configured to introduce external air into the inside of the cover 7. Since the opening portion 71 is provided and the inside of the cover 7 is hollow or filled with soft resin, a gauge resistor may detect an air pressure (for example, an atmospheric pressure) around the MEMS module 60. Further, the provision of the opening portion 71 allows a temperature sensor of an electronic component to detect the temperature around the MEMS module 60. Although only one opening portion 71 is disposed, the number of opening portions 71 is not particularly limited. The extending portion 72 extends from an edge of the opening portion 71 and overlaps with at least a portion of the opening portion 71 in a plan view. Further, in the illustrated configuration, a leading end of the extending portion 72 is provided at a position that avoids the MEMS 200 of the semiconductor chip 2 in a plan view. The extending portion 72 may not be provided.

The bonding material 8 bonds the substrate 1 and the cover 7, and is made of, for example, a paste bonding material containing metal such as Ag. The bonding material 8 is provided in a rectangular and annular shape in a plan view, and a portion of the bonding material 8 is formed in a region overlapping with the insulating layer 1C of the substrate 1 shown in FIG. 2.

### <Operation Example of Barometer>

An example of the operation of the barometer 110 will be described below. The operation of the barometer 110 is not limited to the following operation examples.

An electronic component of the semiconductor chip 2 multiplexes an electrical signal detected by the temperature sensor and an electrical signal detected by the gauge resistor with a multiplexer, and converts the same into a digital signal with an analog/digital conversion circuit. Then, based on the digital signal, a signal processor performs processes such as amplification, filtering, and logic operation while using a storage area of a storage. A signal subjected to the signal processing is output to the outside of the MEMS module 60 via a metal wire and the wiring portion 1B of the substrate 1 shown in FIG. 2. At this time, the electronic component corrects detection information detected by the barometer 110 based on the electrical signal detected by the temperature sensor and the electrical signal detected by the gauge resistance. As a result, it is possible to obtain the barometer 110 configured to correct the signal from which the atmospheric pressure is detected by performing appropriate signal processing with the electronic component, and transmit a signal of the calculated amount of change in the atmospheric pressure to the MEMS 200, thereby accurately deriving a change in an external air pressure.

According to the present embodiment, since the barometer 110 includes the MEMS module 60 configured to suppress the influence of the non-detection target stress, it is possible to obtain the barometer 110 capable of suppressing the influence of the non-detection target stress and making maximum use of its characteristics.

### Other Embodiments

As described above, although some embodiments have been described, the discussion and drawings forming a part of the disclosure are illustrative and should not be construed as limiting. Various alternative embodiments, examples, and operational techniques will become apparent to those skilled in the art from this disclosure. Thus, the present embodiment includes various embodiments and the like that are not described herein.

For example, in the second embodiment, instead of the soft member 3, a hard member such as silver paste may be disposed on the first main surface 2A overlapping with the electrode pads 5 when viewed from the Z direction. As a result, it is possible to improve stability of the semiconductor chip 2 in a wire bonding process and maintain bonding quality. Even in this case, mechanical connection with the hard member 4 is performed at one corner portion, and the soft member 3 is disposed at another corner portion, such that stress due to deformation of the substrate 1 is absorbed by the soft member 3, thereby making it difficult to transmit the stress to the semiconductor chip 2.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A MEMS module comprising:
a substrate;
a semiconductor chip in which a MEMS including a mechanical movable portion is formed; and
a soft member that is interposed between the substrate and the semiconductor chip and has a lower hardness than the substrate,
wherein the soft member is disposed in a partial region of a first main surface of the semiconductor chip facing the substrate.

2. The MEMS module of claim 1, further comprising: a hard member configured to mechanically connect the substrate and the semiconductor chip and have a higher hardness than the soft member,
wherein when the MEMS module is viewed from a normal direction of the first main surface, the hard member is disposed at one of a plurality of corner portions of a periphery of the first main surface.

3. The MEMS module of claim 1, wherein the semiconductor chip includes a plurality of electrode pads that are formed on at least one selected from the group of the first main surface and a second main surface opposite the first main surface and configured to obtain an electrical connection with an outside, and
wherein when the MEMS module is viewed from a normal direction of the first main surface, the plurality of electrode pads are arranged at one of a plurality of corner portions of the first main surface or the second main surface.

4. The MEMS module of claim 2, wherein the hard member is a bump electrode configured to electrically connect the substrate and the semiconductor chip, and
wherein the soft member is disposed in a region other than the one corner portion where the bump electrode is disposed.

5. The MEMS module of claim 4, wherein when the MEMS module is viewed from the normal direction of the first main surface, the soft member is disposed at another corner portion diagonal to the one corner portion where the bump electrode is disposed.

6. The MEMS module of claim 3, wherein the plurality of electrode pads are formed on the second main surface of the semiconductor chip,
wherein the MEMS module further comprises a metal wire electrically connected to the plurality of electrode pads, and
wherein the semiconductor chip is mounted on the substrate via the soft member.

7. The MEMS module of claim 6, wherein when the MEMS module is viewed from the normal direction of the first main surface, the soft member overlaps with the plurality of electrode pads.

8. The MEMS module of claim 1, wherein when the MEMS module is viewed from a normal direction of the first main surface, the soft member is disposed in a peripheral region of the first main surface, which is a region located within a predetermined distance from a periphery toward a center of the semiconductor chip.

9. The MEMS module of claim 8, wherein when the MEMS module is viewed from the normal direction of the first main surface, the soft member is disposed at a corner portion of the peripheral region.

10. The MEMS module of claim 8, wherein when the MEMS module is viewed from the normal direction of the first main surface, the soft member is disposed at an intermediate portion which is a portion excluding a corner portion of the peripheral region from the peripheral region.

11. The MEMS module of claim 1, wherein when the MEMS module is viewed from a normal direction of the first main surface, the soft member includes a portion disposed outside a periphery of the semiconductor chip.

12. The MEMS module of claim 1, wherein when the MEMS module is viewed from a normal direction of the first main surface, the soft member is disposed in a central region that is separated by a predetermined distance from a periphery toward a center of the semiconductor chip.
